(19) United States
(12) Patent Application Publication
(10) Pub. No.: US 2024/0332340 A1
(43) Pub. Date: Oct. 3, 2024

(54) LIGHT IRRADIATION MODULE

(71) Applicant: HOYA CORPORATION, Tokyo (JP)

(72) Inventor: Hiroaki WATANABE, Tokyo (JP)

(73) Assignee: HOYA CORPORATION, Tokyo (JP)

(21) Appl. No.: 18/617,888

(22) Filed: Mar. 27, 2024

(30) Foreign Application Priority Data
Mar. 31, 2023 (JP) 2023-058766

(51) Int. Cl. H01L 27/15; B41F 1/16; B41F 23/08; H01L 33/58

(52) U.S. Cl. CPC H01L 27/156; H01L 33/58; B41F 1/16; B41F 23/08

(57) ABSTRACT

A light irradiation module includes: a substrate; n wiring patterns (n is an integer of 2 or more) on the substrate; and LED elements. Each wiring pattern includes: first to third strip-shaped portions; a first connecting portion connecting the first and second strip-shaped portions; and a second connecting portion connecting the second and third strip-shaped portions. The first strip-shaped portion of an (i+1)-th wiring pattern (i is an integer of 1 to n−1) is disposed between the second and third strip-shaped portions of an i-th wiring pattern. The LED elements are disposed on the second and third strip-shaped portions of each wiring pattern. One electrode of each LED element is connected to the second or third strip-shaped portion immediately thereunder. Other electrodes of the LED elements on the second and third strip-shaped portions of the i-th wiring pattern are connected to the first strip-shaped portion of the (i+1)-th wiring pattern.

### TECHNICAL FIELD

The present disclosure relates to subject matter contained in Japanese Patent Application No. 2023-058766 (filed on Mar. 31, 2023) which is expressly incorporated herein by reference in its entirety.

The present invention relates to a light irradiation module including a plurality of light emitting diodes (LEDs) on a substrate.

### BACKGROUND ART

Theretofore, ultraviolet light irradiation apparatuses have been used to cure ultraviolet curable inks used as inks for sheet-fed offset printing.

Lamp-type irradiation apparatuses using a light source such as a high-pressure mercury vapor lamp or a mercury xenon lamp have heretofore been known as such ultraviolet light irradiation apparatuses. In recent years, ultraviolet light irradiation apparatuses using ultraviolet LEDs as light sources in place of conventional discharge lamps have been put to practical use due to the demands for lower power consumption, longer service lives, and more compact apparatus sizes (e.g., Patent Literature 1).

FIGS. 7A and 7B are diagrams illustrating the configuration of a light irradiation module (ultraviolet light irradiation apparatus) disclosed in Patent Literature 1. FIG. 7A is a plan view of the light irradiation module. FIG. 7B is a diagram illustrating wiring patterns (hatched regions) on a substrate 1 of the light irradiation module. As illustrated in FIG. 7, the light irradiation module disclosed in Patent Literature 1 includes the substrate 1 and a plurality of (40 in FIG. 7A) LED elements 3 placed on a surface of the substrate 1. Moreover, a power supply pattern 6, a ground pattern 7, and a plurality of wiring patterns 8 are formed on the substrate 1.

As illustrated in FIG. 7B, each wiring pattern 8 includes: a strip-shaped portion 8a extending linearly in an X-axis direction; first protruding portions 8b protruding from the strip-shaped portion 8a in a trapezoidal shape in a Y-axis direction; and second protruding portions 8c protruding from the strip-shaped portion 8a in a trapezoidal shape in the opposite direction from the Y-axis direction. The first protruding portions 8b and the second protruding portions 8c of each wiring pattern 8 are formed alternately in the X-axis direction. Between the first protruding portions 8b of each wiring pattern 8 are disposed the second protruding portions 8c of the adjacent wiring pattern 8. Between the second protruding portions 8c of each wiring pattern 8 are disposed the first protruding portions 8b of the adjacent wiring pattern 8.

Also, the power supply pattern 6 has a strip-shaped portion 6a extending linearly in the X-axis direction, and protruding portions 6b protruding from the strip-shaped portion 6a in a trapezoidal shape between the second protruding portions 8c of the adjacent wiring pattern 8 in the Y-axis direction. The ground pattern 7 has a strip-shaped portion 7a extending linearly in the X-axis direction, and protruding portions 7c protruding from the strip-shaped portion 7a in a trapezoidal shape between the first protruding portions 8b of the adjacent wiring pattern 8 in 10) the opposite direction from the Y-axis direction. Moreover, as illustrated in FIG. 7A, on each wiring pattern 8 in Patent Literature 1, five LED elements 3 are disposed respectively at the five first protruding portions 8b, and five LED elements 3 are disposed respectively at positions on the strip-shaped portion 8a corresponding to the five second protruding portions 8c. Also, on the power supply pattern 6, five LED elements 3 are disposed respectively at the five protruding portions 6b, and five LED elements 3 are disposed respectively at positions corresponding to the second protruding portions 8c of the adjacent wiring pattern 8 in the Y-axis direction.

Thus, on each wiring pattern 8 and the power supply pattern 6, 10 LED elements 3 are disposed in two arrays separated in the Y-axis direction, and the 40 LED elements 3 on the substrate 1 are disposed in a staggered pattern as a whole. Moreover, the anode terminal of each LED element 3 is joined to the wiring pattern 8 located immediately under it (specifically, the first protruding portion 8b or the strip-shaped portion 8a) or the power supply pattern 6 (specifically, the protruding portion 6b or the strip-shaped portion 6a) with a die bonding agent. A cathode terminal 4 of each LED element 3 is electrically connected by a wire 5 to the strip-shaped portion 8a or a second protruding portion 8c of the adjacent wiring pattern 8 or the strip-shaped portion 7a or a protruding portion 7c of the ground pattern 7.

### CITATION LIST

### Patent Literature

[Patent Literature 1] Description of Japanese Patent No. 6881874

### SUMMARY

### Technical Problems

As described above, in the configuration of FIG. 7, the LED elements 3 are disposed in a staggered pattern. In this way, when the light irradiation module is moved relative to an irradiation target in the Y-axis direction, the range over the path which the light irradiation module is moved is thoroughly irradiated with rays of ultraviolet light with no gap therebetween.

However, since the LED elements 3 need to be disposed in a staggered pattern, the LED elements 3 on each wiring pattern 8 and the power supply pattern 6 need to be disposed in two arrays separated in the Y-axis direction in order to arrange a plurality of the light irradiation modules in FIG. 7 side by side in the X-axis direction (horizontal direction) and array their LED elements 3 in a continuous and regular fashion. For this reason, an even number of LED elements 3 need to be disposed on each wiring pattern 8 and the power supply pattern 6 (that is, an even number of LED elements 3 need to be connected in parallel). This imposes a limitation on the design of the electric circuit.

Also, there has been a demand for such a light irradiation module to increase the cumulative amount of light (light energy per unit area) on an irradiation target in order to raise the rate of processing of the irradiation target. Here, to increase the cumulative amount of light, it will be necessary to narrow the arrangement pitch of the LED elements 3 in the Y-axis direction as much as possible. In the configuration of FIG. 7, each wire 5 is led out in the Y-axis direction and connected to the adjacent wiring pattern 8 or the ground pattern 7. Thus, there is a physical limitation in narrowing the arrangement pitch of the LED elements 3 in the Y-axis direction as much as possible.

The present invention has been made in view of such circumstances. Some embodiments provide a light irradiation module capable of achieving an improved degree of freedom in the design of its electric circuit and also achieving a narrower arrangement pitch of LED elements in the Y-axis direction (the moving direction relative to an irradiation target) to increase the cumulative amount of light (light energy per unit area) on the irradiation target.

### Solution to Problems

In order to achieve the above object, a light irradiation module of one embodiment includes: a substrate defined by a first direction and a second direction perpendicular to the first direction; n wiring patterns formed on the substrate along the first direction, where n is an integer of 2 or more; and a plurality of LED elements that are disposed on the wiring patterns and emit light in a third direction perpendicular to the first direction and the second direction. Each of the wiring patterns includes: first, second, and third strip-shaped portions extending in the second direction and spaced from one another in the first direction; a first connecting portion electrically connecting the first strip-shaped portion and the second strip-shaped portion; and a second connecting portion electrically connecting the second strip-shaped portion and the third strip-shaped portion. The first strip-shaped portion of an (i+1)-th wiring pattern among the wiring patterns is disposed between the second strip-shaped portion and the third strip-shaped portion of an i-th wiring pattern among the wiring patterns, where i is an integer of 1 to n−1. The plurality of LED elements are disposed along the second direction on the second strip-shaped portion and the third strip-shaped portion of each of the wiring patterns. One electrode of each of the LED elements is electrically connected to the second strip-shaped portion or the third strip-shaped portion located immediately under the LED element. Another electrode of each of the LED elements disposed on the second strip-shaped portion and the third strip-shaped portion of the i-th wiring pattern is electrically connected to the first strip-shaped portion of the (i+1)-th wiring pattern.

In such a configuration, LED elements are disposed on the second strip-shaped portion and the third strip-shaped portion extending in the second direction. In this way, it is possible to narrow the arrangement pitch of the LED elements in the second direction within such a limit that the LED elements do not contact one another. This increases the cumulative amount of light (light energy per unit area) on an irradiation target. Moreover, the number of LED elements to be connected in parallel can be adjusted as the number of LED elements to be disposed on the second strip-shaped portion and the third strip-shaped portion, and the number of LED elements to be connected in series can be adjusted based on the number of wiring patterns. This improves the degree of freedom in the design of the electric circuit.

Also, a light irradiation module of another embodiment according to another aspect includes: a substrate defined by a first direction and a second direction perpendicular to the first direction; n wiring patterns formed on the substrate along the first direction, where n is an integer of 3 or more; and a plurality of LED elements that are disposed on the wiring patterns and emit light in a third direction perpendicular to the first direction and the second direction. Each of the wiring patterns includes: first, second, and third strip-shaped portions extending in the second direction and spaced from one another in the first direction; a first connecting portion electrically connecting the first strip-shaped portion and the second strip-shaped portion; and a second connecting portion electrically connecting the second strip-shaped portion and the third strip-shaped portion. The first strip-shaped portion of an (i+1)-th wiring pattern among the wiring patterns is disposed between the second strip-shaped portion and the third strip-shaped portion of an i-th wiring pattern among the wiring patterns, where i is an integer of 1 to n−2. The second strip-shaped portion of the (i+1)-th wiring pattern is disposed between the third strip-shaped portion of the i-th wiring pattern and the first strip-shaped portion of an (i+2)-th wiring pattern among the wiring patterns. The third strip-shaped portion of the (i+1)-th wiring pattern is disposed between the first strip-shaped portion and the second strip-shaped portion of the (i+2)-th wiring pattern. The plurality of LED elements are disposed along the second direction on the third strip-shaped portion of each of the wiring patterns. One electrode of each of the LED elements is electrically connected to the third strip-shaped portion located immediately under the LED element. Another electrode of each of the LED elements disposed on the third strip-shaped portion of the i-th wiring pattern is electrically connected to the first strip-shaped portion or the second strip-shaped portion of the (i+1)-th wiring pattern.

In such a configuration, LED elements are disposed on the third strip-shaped portion extending in the second direction. In this way, it is possible to narrow the arrangement pitch of the LED elements in the second direction within such a limit that the LED elements do not contact one another. This increases the cumulative amount of light (light energy per unit area) on an irradiation target. Moreover, the number of LED elements to be connected in parallel can be adjusted as the number of LED elements to be disposed on the third strip-shaped portion, and the number of LED elements to be connected in series can be adjusted based on the number of wiring patterns. This improves the degree of freedom in the design of the electric circuit.

Assuming the plurality of LED elements disposed on each of the wiring patterns as a single LED element group, each of the LED element groups may be disposed at a predetermined interval in the first direction.

An arrangement pitch of the LED elements in each of the LED element groups in the first direction may be wider than an arrangement pitch of the LED elements in the second direction.

The light irradiation module may further include cylindrical lenses disposed so as to cover the LED element groups.

When a plurality of the light irradiation modules are coupled in the first direction, an interval in the first direction between the closest LED element groups between adjacent ones of the light irradiation modules may be substantially equal to the predetermined interval.

The plurality of LED elements may be arranged in a single array along the second direction.

The plurality of LED elements may be arranged in a plurality of arrays along the second direction.

The first connecting portion may be a strip-shaped pattern extending in the first direction between the first strip-shaped portion and the second strip-shaped portion.

The second connecting portion may be a strip-shaped pattern extending in the first direction between the second strip-shaped portion and the third strip-shaped portion.

The light irradiation module may move in the second direction relative to an irradiation target to be irradiated with the light.

Also, a light irradiation module of another embodiment according to another aspect includes: a substrate defined by a first direction and a second direction perpendicular to the first direction; n wiring patterns formed on the substrate along the first direction, where n is an integer of 2 or more; and a plurality of light emitting diode (LED) elements that are disposed on the wiring patterns and emit light in a third direction perpendicular to the first direction and the second direction. Each of the wiring patterns includes: first, second, and third strip-shaped portions extending in the second direction and spaced from one another in the first direction; a first connecting portion electrically connecting the first strip-shaped portion and the second strip-shaped portion; and a second connecting portion electrically connecting the second strip-shaped portion and the third strip-shaped portion.

Such a configuration improves the degree of freedom in the design of the electric circuit.

According to some embodiments as described above, it is possible to implement a light irradiation module capable of achieving an improved degree of freedom in the design of its electric circuit and also achieving a narrower arrangement pitch of LED elements in the Y-axis direction (the moving direction relative to an irradiation target) to increase the cumulative amount of light (light energy per unit area) on the irradiation target.

### BRIEF DESCRIPTION OF DRAWINGS

FIGS. 1A to 1C are diagrams explaining a configuration of a light irradiation module according to a first embodiment described herein.

FIG. 2 is a diagram explaining a configuration of a light irradiation module according to a second embodiment described herein.

FIG. 3 is a diagram explaining a configuration of a light irradiation module according to a third embodiment described herein.

FIGS. 4A and 4B are diagrams explaining a configuration of a light irradiation module according to a fourth embodiment described herein.

FIGS. 5A to 5C are diagrams explaining a configuration of a light irradiation module according to a fifth embodiment described herein.

FIGS. 6A and 6B are diagrams explaining a configuration of a light irradiation module according to a sixth embodiment described herein.

FIGS. 7A and 7B are diagrams explaining a configuration of a conventional light irradiation module.

### DESCRIPTION OF EMBODIMENTS

Some embodiments of the present invention will be described below in detail with reference to drawings. Note that identical or equivalent portions in drawings are denoted by the same reference sign, and description thereof will not be repeated.

### First Embodiment

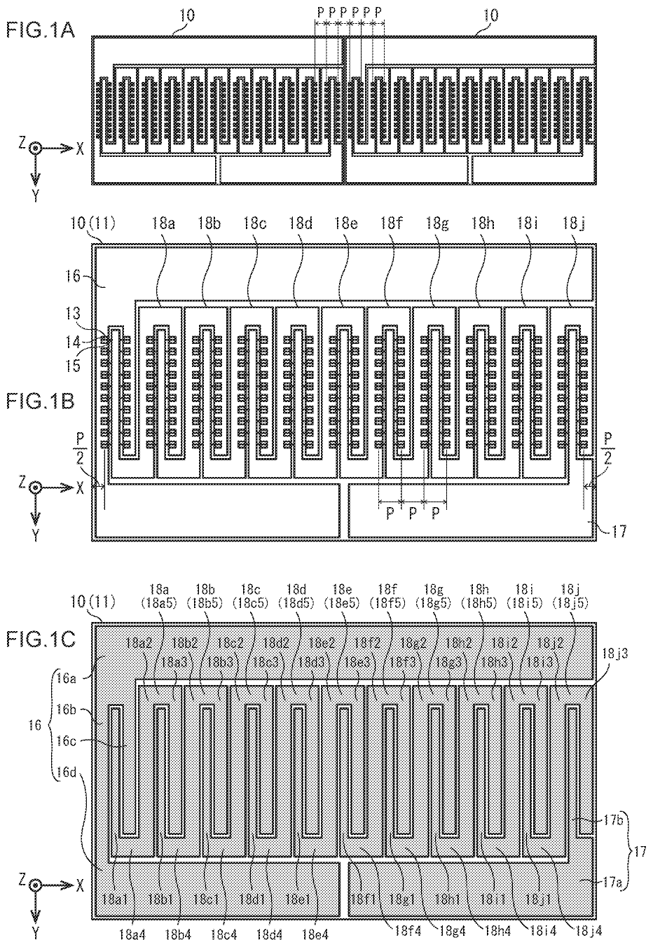

FIGS. 1A to 1C are diagrams explaining a schematic configuration of a light irradiation module 10 according to a first embodiment described herein. FIG. 1A is a plan view illustrating a configuration in which a plurality of the light irradiation modules 10 according to the present embodiment are coupled. FIG. 1B is an enlarged plan view of the light irradiation module 10. FIG. 1C is a wiring pattern diagram of the light irradiation module 10. The light irradiation module 10 according to the present embodiment is a device that is mounted on an ultraviolet light irradiation apparatus or the like and irradiates an irradiation target with ultraviolet light. Generally, one or more light irradiation modules 10 are disposed on a base not illustrated (e.g., a heat sink) and accommodated inside the ultraviolet light irradiation apparatus. Note that the description will be given herein with the Z-axis direction defined as the direction of travel of ultraviolet light emitted from the light irradiation module 10, the X-axis direction as the direction in which wiring patterns 18 extend (the horizontal direction in FIGS. 1A-1C), and the Y-axis direction as the direction perpendicular to the X-axis direction and the Z-axis direction (the vertical direction in FIGS. 1A-1C).

As illustrated in FIG. 1A, the light irradiation module 10 according to the present embodiment is configured such that a plurality of the light irradiation modules 10 can be coupled in the X-axis direction. LED elements 13 are disposed on the coupled light irradiation modules 10 in such a relationship as to be continuous with each other (specifically, the LED elements 13 maintain the same arrangement pitch p in the X-axis direction).

As illustrated in FIG. 1B, the light irradiation module 10 according to the present embodiment includes a substrate 11 and a plurality of (220 in FIG. 1B) LED elements 13 placed on a surface of the substrate 11.

The substrate 11 is a rectangular ceramic substrate made of aluminum nitride, which has high thermal conductivity, for example. On its surface, a power supply pattern 16, a ground pattern 17, and a plurality of (10 in FIGS. 1A to 1C) wiring patterns 18a to 18j are formed.

The power supply pattern 16, the ground pattern 17, and the wiring patterns 18a to 18j are each a thin film of a metal (e.g., copper or gold) that supplies electric power to the LED elements 13.

The power supply pattern 16 is a pattern to be electrically connected to a power supply terminal (not illustrated) of an external power supply device (not illustrated). In the present embodiment, it includes: a first power supply pattern 16a extending in the X-axis direction along the upper edge of the substrate 11; a second power supply pattern 16b extending in the Y-axis direction along the left edge of the substrate 11; a third power supply pattern 16c spaced from the second power supply pattern 16b in the X-axis direction and extending in parallel to the second power supply pattern 16b; and a fourth power supply pattern 16d extending along the lower edge of the substrate 11 from the left edge of the substrate 11 substantially to the center of the substrate 11 (FIG. 1C).

The ground pattern 17 is a pattern to be electrically connected a ground terminal (not illustrated) of the external power supply device. In the present embodiment, it includes: a first ground pattern 17a extending along the lower edge of the substrate 11 substantially from the center of the substrate 11 to the right edge of the substrate 11; and a second ground pattern 17b extending in the Y-axis direction along the right edge of the substrate 11 (FIG. 1C).

The wiring patterns 18a to 18j assume an S-shape turned 90 degrees clockwise, and respectively include: first strip-shaped portions 18a1 to 18j1, second strip-shaped portions 18a2 to 18j2, and third strip-shaped portions 18a3 to 18j3 extending linearly in the Y-axis direction; first connecting portions 18a4 to 18j4 electrically connecting the first strip-shaped portions 18al to 18j1 and the second strip-shaped portions 18a2 to 18j2 at their ends in the Y-axis direction, respectively; and second connecting portions 18a5 to 18j5 electrically connecting the second strip-shaped portions 18a2 to 18j2 and the third strip-shaped portions 18a3 to 18j3 at their ends in the opposite direction from the Y-axis direction, respectively (FIG. 1C). Note that, in this description, the wiring patterns 18a to 18j may be representatively referred to as “wiring pattern 18”, the first strip-shaped portions 18al to 18j1 may be representatively referred to as “first strip-shaped portion 18-1”, the second strip-shaped portions 18a2 to 18j2 may be representatively referred to as “second strip-shaped portion 18-2”, and the third strip-shaped portions 18a3 to 18j3 may be representatively referred to as “third strip-shaped portion 18-3”.

As illustrated in FIGS. 1B and 1C, in the present embodiment, between the second strip-shaped portions 18a2 to 1812 and the third strip-shaped portions 18a3 to 1813 of the wiring patterns 18a to 18i are disposed the first strip-shaped portions 18b1 to 18j1 of the adjacent wiring patterns 18b to 18j, respectively.

Specifically, assuming the wiring patterns 18a to 18j as the 1st to 10th wiring patterns 18 in the order described, the first strip-shaped portion 18-1 of the (i+1)-th wiring pattern 18 (i is an integer from 1 to 9) is disposed between the second strip-shaped portion 18-2 and the third strip-shaped portion 18-3 of the i-th wiring pattern 18.

Moreover, in the present embodiment, the first strip-shaped portion 18al of the wiring pattern 18a is disposed between the second power supply pattern 16b and the third power supply pattern 16c, and the second ground pattern 17b is disposed between the second strip-shaped portion 18j2 and the third strip-shaped portion 18j3 of the wiring pattern 18j (i.e., 10th wiring pattern 18).

Furthermore, as illustrated in FIG. 1B, 10 LED elements 13 are disposed on each of the second power supply pattern 16b, the third power supply pattern 16c, and the second strip-shaped portions 18a2 to 18j2 and the third strip-shaped portions 18a3 to 18j3 of the wiring patterns 18a to 18j at a predetermined arrangement pitch (e.g, approximately 2 mm) in the Y-axis direction. Note that the LED elements 13 disposed on the second power supply pattern 16b, the third power supply pattern 16c, and the second strip-shaped portions 18a2 to 18j2 and the third strip-shaped portions 18a3 to 18j3 of the wiring patterns 18a to 18j are arrayed at the predetermined arrangement pitch p (e.g., approximately 3.5 mm) in the X-axis direction. In sum, the LED elements 13 in the present embodiment are arrayed in the X-axis direction and the Y-axis direction in a 22 (X-axis direction)×10 (Y-axis direction) layout as a whole.

Incidentally, in the present embodiment, the LED elements 13 on the second power supply pattern 16b at the leftmost position (on the minus side in the X-axis direction) are disposed at positions away from the left edge of the substrate 11 by p/2. The LED elements 13 on the third strip-shaped portion 18j3 of the wiring pattern 18j at the rightmost position (on the plus side in the X-axis direction) are disposed at positions away from the right edge of the substrate 11 by p/2. In a state where a plurality of the light irradiation modules 10 are coupled in the X-axis direction, the LED elements 13 disposed on the coupled light irradiation modules 10 are in such a relationship as to be continuous with each other (specifically, the LED elements 13 maintain the same arrangement pitch p in the X-axis direction) (FIGS. 1A and 1B).

Also, in the present embodiment, the arrangement pitch of the LED elements 13 in the Y-axis direction is set narrower than the arrangement pitch p in the X-axis direction. In this way, the irradiation intensity in the X-axis direction is substantially uniform while the cumulative amount of light (light energy per unit area) on an irradiation target is increased.

Each of the LED elements 13 has, for example, a rectangular outer shape measuring 2.0 mm (X-axis direction length)×2.0 mm (Y-axis direction length) in plan view (FIG. 1B), and includes a cathode terminal 14 at the upper surface and an anode terminal (not illustrated) at the lower surface. The anode terminal (one electrode) of each LED element 13 is joined to the second power supply pattern 16b, the third power supply pattern 16c, the corresponding one of the second strip-shaped portions 18a2 to 18j2, or the corresponding one of the third strip-shaped portions 18a3 to 18j3 lying directly under the anode terminal with a die bonding agent (not illustrated). The die bonding agent is a material for mechanically and electrically joining the LED element 13 to the second power supply pattern 16b, the third power supply pattern 16c, the corresponding one of the second strip-shaped portions 18a2 to 18j2, or the corresponding one of the third strip-shaped portions 18a3 to 18j3. In one example, silver (Ag) paste, which is electrically conductive, is used. The cathode terminal 14 (other electrode) of each LED element 13 is electrically connected to the corresponding one of the first strip-shaped portions 18al to 18j1 of the adjacent one of the wiring patterns 18a to 18j by a wire 15 led out in the X-axis direction.

Specifically, assuming the wiring patterns 18a to 18j as the 1st to 10th wiring patterns 18 in the order described, the cathode terminals 14 of the LED elements 13 disposed on the second strip-shaped portion 18-2 and the third strip-shaped portion 18-3 of the i-th wiring pattern 18 (i is an integer from 1 to 9) are electrically connected to the first strip-shaped portion 18-1 of the adjacent (i+1)-th wiring pattern 18.

The cathode terminals 14 of the LED elements 13 disposed on the second power supply pattern 16b and the third power supply pattern 16c are electrically connected to the first strip-shaped portion 18al of the adjacent wiring pattern 18a. The cathode terminals 14 of the LED elements 13 disposed on the second strip-shaped portion 18j2 and the third strip-shaped portion 18j3 of the wiring pattern 18j (i.e., the 10th wiring pattern 18) are electrically connected to the adjacent second ground pattern 17b.

As described above, in the light irradiation module 10 according to the present embodiment, the 10 LED elements 13 disposed on the second power supply pattern 16b and the 10 LED elements 13 disposed on the third power supply pattern 16c are connected in parallel. The 10 LED elements 13 disposed on each of the second strip-shaped portions 18a2 to 18j2 of the wiring patterns 18a to 18j and the 10 LED elements 13 disposed on each of the third strip-shaped portions 18a3 to 18j3 are connected in parallel. Each 20 LED elements 13 connected in parallel are connected in series by the corresponding one of the first strip-shaped portions 18al to 18j1 of the wiring patterns 18a to 18j. Specifically, assuming each 20 LED elements 13 connected in parallel as a single LED element group, there are 11 groups of LED elements 13 connected in series, and these LED element groups are disposed at predetermined intervals in the X-axis direction.

Thus, the 220 LED elements 13 can be simultaneously driven by connecting the power supply terminal (not illustrated) of the external power supply device (not illustrated) to the power supply pattern 16, connecting the ground terminal (not illustrated) of the external power supply device to the ground pattern 17, and applying a predetermined driving voltage Vp. If an operating voltage Vf of each LED element 13 is 5 (v), the driving voltage Vp to be applied for the whole light irradiation module 10 will be Vp=5 (v)×11 groups=55 (v).

As described above, in the light irradiation module 10 according to the present embodiment, LED elements 13 are disposed on the second power supply pattern 16b, the third power supply pattern 16c, the second strip-shaped portions 18a2 to 18j2, and the third strip-shaped portions 18a3 to 18j3, which extend linearly in the Y-axis direction, and the cathode terminal 14 of each LED element 13 is connected to the corresponding one of the first strip-shaped portions 18al to 18j1 by a wire 15 led out in the X-axis direction.

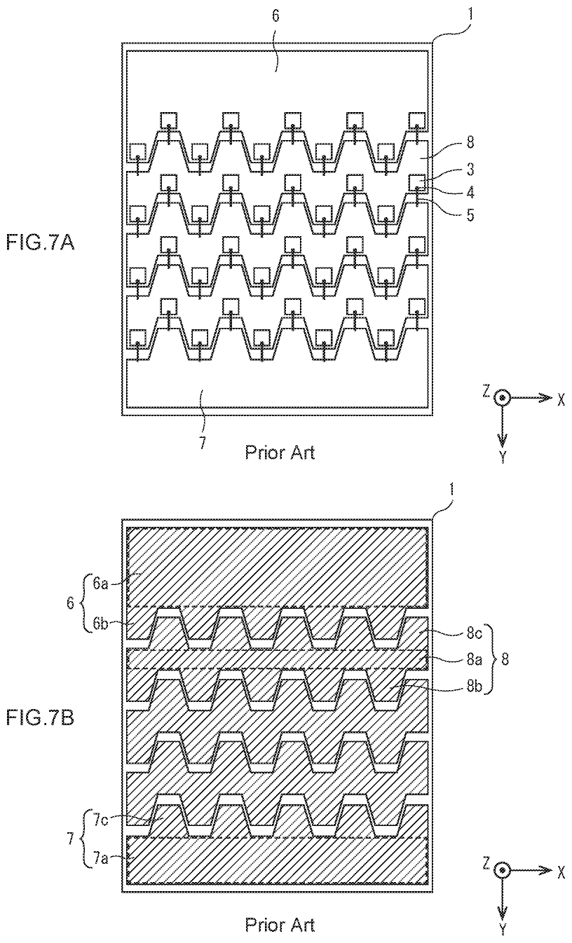

The configuration in the present embodiment allows the arrangement pitch of the LED elements 13 in the Y-axis direction to be narrowed within such a limit that the LED elements 13 do not contact one another, and is free from the physical limitation in the conventional art (FIG. 7). That is, the density of LED elements 13 in the Y-axis direction can be freely set.

Also, in the present embodiment, the circuit configuration is such that the 10 wiring patterns 18a to 18j connect groups of 20 LED elements 13 in parallel and connect the 11 groups of LED elements 13 in series. Alternatively, the number of LED elements 13 (the number of groups) can be changed as appropriate by increasing or decreasing the number of wiring patterns 18 as appropriate. This improves the degree of freedom in the design of the electric circuit.

As described above, the light irradiation module 10 according to the present embodiment is configured such that a plurality of the light irradiation modules 10 can be coupled in the X-axis direction, and the LED elements 13 disposed on the coupled light irradiation modules 10 are in such a relationship as to be continuous with each other (specifically, the LED elements 13 maintain the same arrangement pitch p in the X-axis direction) (FIG. 1A).

Thus, ultraviolet light having substantially uniform irradiation intensity in the X-axis direction will be emitted from each coupled light irradiation module 10. By coupling a plurality of the light irradiation modules 10 in the X-axis direction, it is possible to freely set the irradiation width in the X-axis direction.

The above description is provided for explaining the embodiments of the present invention, but the present invention should not be limited to the configurations of the aforementioned embodiments, but may be modified in various ways within the scope of the technical idea.

For example, in the light irradiation module 10 according to the present embodiment described above, 220 LED elements 13 are arrayed in a 22 (X-axis direction)×10 (Y-axis direction) layout. However, the number of LED elements 13 and the number of arrays of LED elements 13 are not limited, and can be selected as appropriate according to the specifications.

Also, the LED elements 13 in the present embodiment described above emit ultraviolet light but are not limited to such a configuration. For example, the LED elements 13 may be configured to emit visible or infrared light.

Also, the LED element 13 in the present embodiment are disposed on the second power supply pattern 16b, the third power supply pattern 16c, and the second strip-shaped portions 18a2 to 18j2 and the third strip-shaped portions 18a3 to 18j3 of the wiring patterns 18a to 18j, which extend linearly in the Y-axis direction, but are not necessarily limited to such a configuration. For example, LED elements 13 may be disposed additionally on the first connecting portions 18a4 to 18j4 and the second connecting portions 18a5 to 18j5 of the wiring patterns 18a to 18j. In this case, the cathode terminals 14 of the LED elements 13 disposed on the first connecting portions 18a4 to 18j4 and the second connecting portions 18a5 to 18j5 are connected to the adjacent first strip-shaped portions 18al to 18j1 by wires 15 led out in the Y-axis direction.

### Second Embodiment

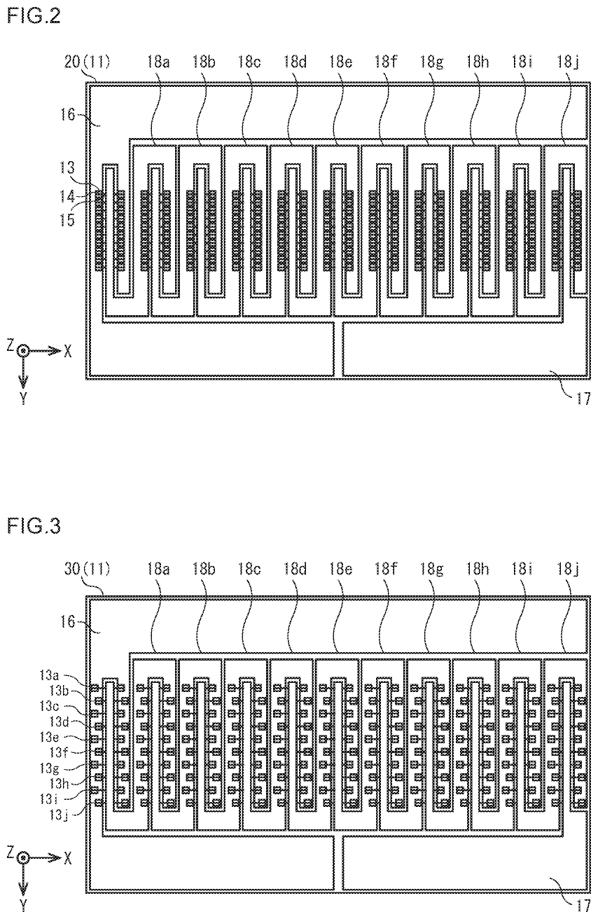

FIG. 2 is a plan view explaining a schematic configuration of a light irradiation module 20 according to a second embodiment described herein. The light irradiation module 20 according to the present embodiment differs from the light irradiation module 10 according to the first embodiment in that the arrangement pitch of the LED elements 13 in the Y-axis direction is narrower than that in the light irradiation module 10 according to the first embodiment and is set to approximately 1.3 mm, for example.

As illustrated in FIG. 2, the LED elements 13 in the present embodiment are disposed on the second power supply pattern 16b, the third power supply pattern 16c, and the second strip-shaped portions 18a2 to 18j2 and the third strip-shaped portions 18a3 to 18j3 of the wiring patterns 18a to 18j, which extend linearly in the Y-axis direction, like the light irradiation module 10 according to the first embodiment (FIGS. 1C and 2). The arrangement pitch of the LED elements 13 in the Y-axis direction in the present embodiment can be freely set within such a limit that the LED elements 13 do not contact one another. Thus, the cumulative amount of light (light energy per unit area) on an irradiation target can be set according to the specifications.

### Third Embodiment

FIG. 3 is a plan view explaining a schematic configuration of a light irradiation module 30 according to a third embodiment described herein. The light irradiation module 30 according to the present embodiment differs from the light irradiation module 10 according to the first embodiment in that 10 LED elements 13a to 13j arrayed in the Y-axis direction are disposed in a zigzag pattern.

More specifically, the LED elements 13a to 13j in the present embodiment are disposed on the second power supply pattern 16b, the third power supply pattern 16c, and the second strip-shaped portions 18a2 to 18j2 and the third strip-shaped portions 18a3 to 18j3 of the wiring patterns 18a to 18j, which extend linearly in the Y-axis direction, like the light irradiation module 10 according to the first embodiment (FIGS. 1C and 3). However, the LED elements 13a, 13c, 13e, 13g, and 13i are disposed to be shifted from the LED elements 13b, 13d, 13f, 13h, and 13j toward the minus side in the X-axis direction. That is, the light irradiation module 30 is configured such that the LED elements 13a, 13c, 13e, 13g, and 13i are disposed in a single array in the Y-axis direction and the LED elements 13b, 13d, 13f, 13h, and 13j are disposed in a single array in the Y-axis direction (in sum, the LED elements 13a to 13j are disposed in a plurality of arrays in the Y-axis direction).

Such a configuration makes it possible to thoroughly (uniformly) apply ultraviolet light onto an irradiation target moved relative to the light irradiation module 30 in the Y-axis direction.

### Fourth Embodiment

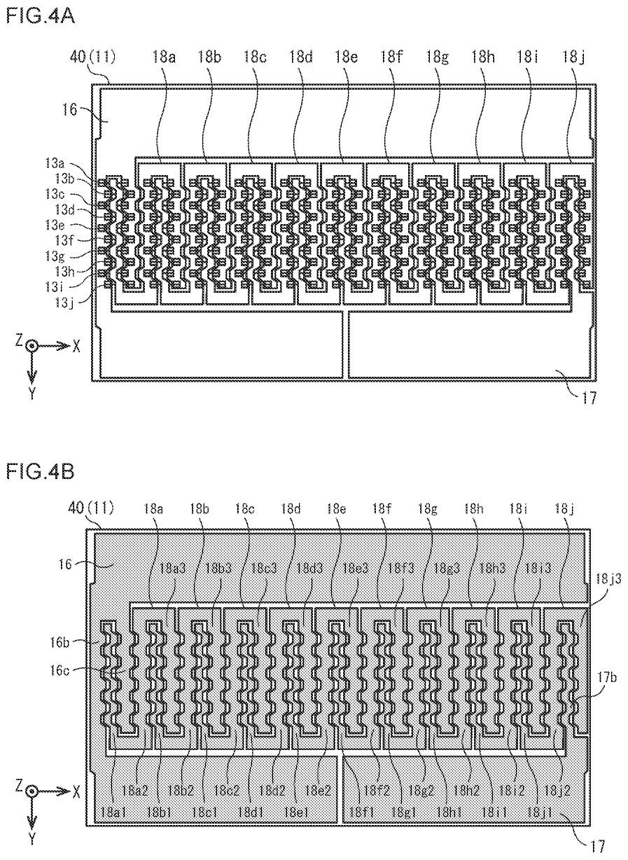

FIGS. 4A and 4B are diagrams explaining a schematic configuration of a light irradiation module 40 according to a fourth embodiment described herein. FIG. 4A is an enlarged plan view of the light irradiation module 40. FIG. 4B is a wiring pattern diagram of the light irradiation module 40. The light irradiation module 40 according to the present embodiment differs from the light irradiation module 30 according to the third embodiment in that the second power supply pattern 16b, the third power supply pattern 16c, the first strip-shaped portions 18al to 18j1, the second strip-shaped portions 18a2 to 18j2, and the third strip-shaped portions 18a3 to 18j3 of the wiring patterns 18a to 18j, and the second ground pattern 17b, which extend linearly in the Y-axis direction, are each formed in a zigzag shape corresponding to the arrangement of the LED elements 13a to 13j.

As described above, the second power supply pattern 16b, the third power supply pattern 16c, the first strip-shaped portions 18al to 18j1, the second strip-shaped portions 18a2 to 18j2, and the third strip-shaped portions 18a3 to 18j3 of the wiring patterns 18a to 18j, and the second ground pattern 17b, which extend linearly in the Y-axis direction, do not necessarily have to be straight and may be in a shape extending in the Y-axis direction which corresponds to the arrangement of the LED elements 13a to 13j.

### Fifth Embodiment

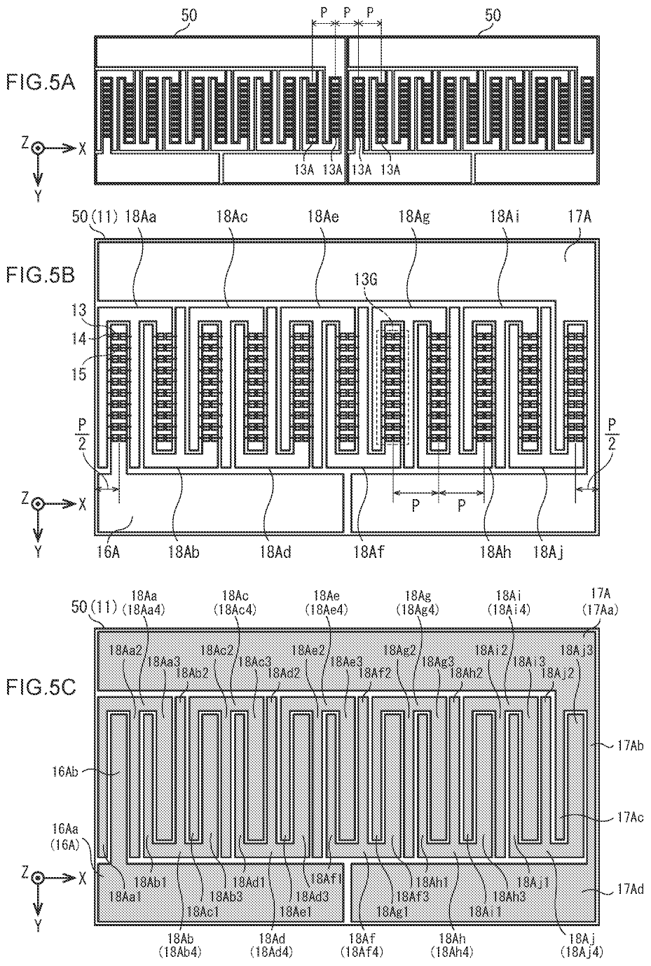

FIGS. 5A to 5C are diagrams explaining a schematic configuration of a light irradiation module 50 according to a fifth embodiment described herein. FIG. 5A is a plan view illustrating a configuration in which a plurality of the light irradiation modules 50 according to the present embodiment are coupled. FIG. 5B is an enlarged plan view of the light irradiation module 50. FIG. 5C is a wiring pattern diagram of the light irradiation module 50. The light irradiation module 50 according to the present embodiment differs from the light irradiation module 10 according to the first embodiment in that a power supply pattern 16A, a ground pattern 17A, and a plurality of (10 in FIG. 5) wiring patterns 18Aa to 18Aj have different shapes and LED elements 13 is disposed differently.

As illustrated in FIG. 5A, like the light irradiation module 10 according to the first embodiment, the light irradiation module 50 according to the present embodiment is also configured such that a plurality of the light irradiation modules 50 can be coupled in the X-axis direction, and LED elements groups 13G disposed on the coupled light irradiation modules 50 are in such a relationship as to be continuous with each other (specifically, the LED element groups 13G maintain the same arrangement pitch p in the X-axis direction) (FIG. 1A).

The power supply pattern 16A is a pattern to be electrically connected to a power supply terminal (not illustrated) of an external power supply device (not illustrated). In the present embodiment, the power supply pattern 16A includes a first power supply pattern 16Aa extending along the lower edge of the substrate 11 from the left edge of the substrate 11 substantially to the center of the substrate 11; and a second power supply pattern 16Ab extending in the Y-axis direction along the left edge of the substrate 11 (FIG. 5C).

The ground pattern 17A includes: a first ground pattern 17Aa extending in the X-axis 10) direction along the upper edge of the substrate 11; a second ground pattern 17Ab extending in the Y-axis direction along the right edge of the substrate 11; a third ground pattern 17Ac spaced from the second ground pattern 17Ab toward the minus side in the X-axis direction and extending in parallel to the second ground pattern 17Ab; and a fourth ground pattern 17Ad extending along the lower edge of the substrate 11 from the right edge of the substrate 11 substantially to the center of the substrate 11 (FIG. 5C).

The wiring patterns 18Aa to 18Aj assume an E-shape turned 90 degrees clockwise or counterclockwise, and respectively include: first strip-shaped portions 18Aa1 to 18Aj1, second strip-shaped portions 18Aa2 to 18Aj2, and third strip-shaped portions 18Aa3 to 18Aj3 extending linearly in the Y-axis direction; and first connecting portions 18Aa4 to 18j4 electrically connecting the first strip-shaped portions 18Aa1 to 18Aj1, the second strip-shaped portions 18Aa2 to 18Aj2, and the third strip-shaped portions 18Aa3 to 18Aj3 at their ends on the plus or minus side in the Y-axis direction (FIG. 5C). Note that, in this description, the wiring patterns 18Aa to 18Aj may be representatively referred to as “wiring pattern 18A”, the first strip-shaped portions 18Aa1 to 18Aj1 may be representatively referred to as “first strip-shaped portion 18A-1”, the second strip-shaped portions 18Aa2 to 18Aj2 may be representatively referred to as “second strip-shaped portion 18A-2”, and the third strip-shaped portions 18Aa3 to 18Aj3 may be representatively referred to as “third strip-shaped portion 18A-3”.

As illustrated in FIGS. 5B and 5C, in the present embodiment, between the second strip-shaped portions 18Aa2 to 18Ah2 and the third strip-shaped portions 18Aa3 to 18Ah3 of the wiring patterns 18Aa to 18Ah are disposed the first strip-shaped portions 18Ab1 to 18Aj1 of the adjacent wiring patterns 18Ab to 18Aj, respectively. Between the third strip-shaped portions 18Aa3 to 18Ah3 of the wiring patterns 18Aa to 18Ah and the first strip-shaped portion 18Ac1 to 18Aj1 of the wiring patterns 18Ac to 18Aj are disposed the second strip-shaped portions 18Ab2 to 18Ai2 of the wiring patterns 18Ab to 18Ai, respectively. Between the first strip-shaped portions 18Ac1 to 18Ah1 of the wiring patterns 18Ac to 18Aj and the second strip-shaped portion 18Ab2 to 18Ai2 of the wiring patterns 18Ab to 18Ai are disposed the third strip-shaped portions 18Ab3 to 18Ai3 of the wiring patterns 18Ab to 18Ai, respectively.

Specifically, assuming the wiring patterns 18Aa to 18Aj as the 1st to 10th wiring patterns 18A in the order described, the first strip-shaped portion 18A-1 of the (i+1)-th wiring pattern 18A (i is an integer from 1 to 8) is disposed between the second strip-shaped portion 18A-2 and the third strip-shaped portion 18A-3 of the i-th wiring pattern 18A. The second strip-shaped portion 18A-2 of the (i+1)-th wiring pattern 18A is disposed between the third strip-shaped portion 18A-3 of the i-th wiring pattern 18A and the first strip-shaped portion 18A-1 of the (i+2)-th wiring pattern 18A. The third strip-shaped portion 18A-3 of the (i+1)-th wiring pattern 18A is disposed between the first strip-shaped portion 18A-1 and the second strip-shaped portion 18A-2 of the (i+2)-th wiring pattern 18A.

Also, in the present embodiment, the second power supply pattern 16Ab is disposed between the first strip-shaped portion 18Aa1 and the second strip-shaped portion 18Aa2 of the wiring pattern 18Aa (i.e., first wiring pattern 18A). The third ground pattern 17Ac is disposed between the second strip-shaped portion 18Aj2 and the third strip-shaped portion 18Aj3 of the wiring pattern 18Aj (i.e., 10th wiring pattern 18A).

Moreover, as illustrated in FIG. 5B, LED elements 13 are arrayed in a 2 (X-axis direction)×10 (Y-axis direction) layout on each of the second power supply pattern 16Ab and the third strip-shaped portions 18Aa3 to 18Aj3 of the wiring patterns 18Aa to 18Aj. In the present embodiment, assuming the 20 LED elements 13 disposed on each of the second power supply pattern 16Ab and the third strip-shaped portions 18Aa3 to 18Aj3 of the wiring patterns 18Aa to 18Aj as a single LED element group 13G, these LED element groups 13G are arrayed at a predetermined arrangement pitch p (e.g., approximately 7.0 mm) in the X-axis direction.

Incidentally, in the present embodiment, the LED element group 13G on the second power supply pattern 16Ab at the leftmost position (on the minus side in the X-axis direction) is disposed at a position away from the left edge of the substrate 11 by p/2. The LED element group 13G on the third strip-shaped portion 18Aj3 of the wiring pattern 18Aj at the rightmost position (on the plus side in the X-axis direction) is disposed at a position away from the right edge of the substrate 11 by p/2. In a state where a plurality of the light irradiation modules 50 are coupled in the X-axis direction, the LED element groups 13G disposed on the coupled light irradiation modules 50 are in such a relationship as to be continuous with each other (specifically, the LED element groups 13G maintain the same arrangement pitch p in the X-axis direction) (FIGS. 5A and 5B).

Also, in the present embodiment, the arrangement pitch of the LED element groups 13G in the Y-axis direction is set narrower than the arrangement pitch p in the X-axis direction. In this way, the irradiation intensity in the X-axis direction is substantially uniform while the cumulative amount of light (light energy per unit area) on an irradiation target is increased.

As in the first embodiment, each of the LED elements 13 has, for example, a rectangular outer shape measuring 2.0 mm (X-axis direction length)×2.0 mm (Y-axis direction length) in plan view (FIG. 5B), and includes a cathode terminal 14 at the upper surface and an anode terminal (not illustrated) at the lower surface. The anode terminal (one electrode) of each LED element 13 is joined to the second power supply pattern 16Ab or the corresponding one of the third strip-shaped portions 18Aa3 to 18Aj3 lying directly under the anode terminal with a die bonding agent (not illustrated). The cathode terminal 14 (other electrode) of each LED element 13 is electrically connected to the one of the second strip-shaped portions 18Ab2 to 18Aj2 or the third strip-shaped portions 18Ab3 to 18Aj3 of the adjacent one of the wiring patterns 18b to 18j by a wire 15 led out in the X-axis direction.

Specifically, assuming the wiring patterns 18Aa to 18Aj as the 1st to 10th wiring patterns 18A in the order described, the cathode terminals 14 of the LED elements 13 disposed on the third strip-shaped portion 18A-3 of the i-th wiring pattern 18A (i is an integer from 1 to 9) are electrically connected to the first strip-shaped portion 18A-1 or the second strip-shaped portion 18A-2 of the adjacent (i+1)-th wiring pattern 18A.

The cathode terminals 14 of the LED elements 13 disposed on the second power supply pattern 16Ab are electrically connected to the first strip-shaped portion 18Aa1 or the second strip-shaped portion 18Aa2 of the adjacent wiring pattern 18Aa. The cathode terminals 14 of the LED elements 13 disposed on the third strip-shaped portion 18Aj3 of the wiring pattern 18Aj (i.e., the 10th wiring pattern 18A) are electrically connected to the adjacent second ground pattern 17Ab or the third ground pattern 17Ac.

As described above, in the light irradiation module 50 according to the present embodiment, the 20 LED elements 13 disposed on the second power supply pattern 16Ab are connected in parallel, and the 20 LED elements 13 disposed on each of the third strip-shaped portions 18Aa3 to 18Aj3 of the wiring patterns 18Aa to 18Aj are connected in parallel. Each 20 LED elements 13 connected in parallel (i.e., each LED element group 13G) are connected in series by the corresponding ones of the first strip-shaped portions 18Aa1 to 18Aj1 and the second strip-shaped portions 18Aa2 to 18Aj2 of the wiring patterns 18Aa to 18Aj. Specifically, assuming each 20 LED elements 13 connected in parallel as a single LED element group 13G, there are 11 LED element groups 13G connected in series, and these LED element groups 13G are disposed at predetermined intervals in the X-axis direction.

As described above, in the light irradiation module 50 according to the present embodiment, LED element groups 13G are disposed on the second power supply pattern 16Ab and the third strip-shaped portions 18Aa3 to 18Aj3, which extend linearly in the Y-axis direction, and the cathode terminal 14 of each LED element 13 is connected to the corresponding one of the first strip-shaped portions 18Aa1 to 18Aj1 or the second strip-shaped portions 18Aa2 to 18Aj2 by a wire 15 led out in the X-axis direction.

The configuration in the present embodiment allows the arrangement pitch of the LED elements 13 in the Y-axis direction to be narrowed within such a limit that the LED elements 13 do not contact one another, and is free from the physical limitation in the conventional art (FIG. 7). That is, the density of LED elements 13 in the Y-axis direction can be freely set.

Also, in the present embodiment, the circuit configuration is such that the 10 wiring patterns 18Aa to 18Aj connect groups of 20 LED elements 13 in parallel and connect the 11 LED element groups 13G in series. Alternatively, the number of LED element groups 13G (the number of groups) can be changed as appropriate by increasing or decreasing the number of wiring patterns 18A as appropriate. This improves the degree of freedom in the design of the electric circuit.

As described above, the light irradiation module 50 according to the present embodiment is configured such that a plurality of the light irradiation modules 50 can be coupled in the X-axis direction, and the LED element groups 13G disposed on the coupled light irradiation modules 50 are in such a relationship as to be continuous with each other (specifically, the LED element groups 13G maintain the same arrangement pitch p in the X-axis direction) (FIG. 5A).

Thus, ultraviolet light having substantially uniform irradiation intensity in the X-axis direction will be emitted from each coupled light irradiation module 50. By coupling a plurality of the light irradiation modules 50 in the X-axis direction, it is possible to freely set the irradiation width in the X-axis direction.

### Sixth Embodiment

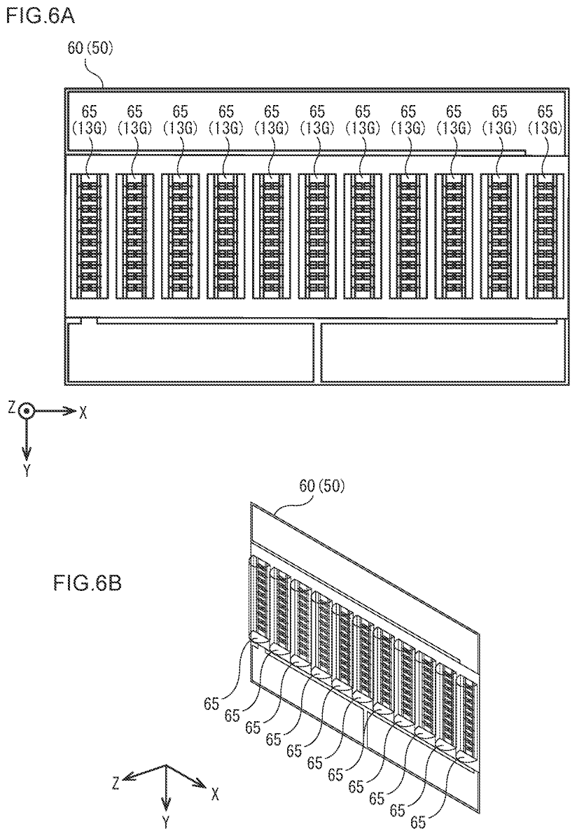

FIGS. 6A and 6B are diagrams explaining a schematic configuration of a light irradiation module 60 according to a sixth embodiment described herein. FIG. 6A is a plan view, and FIG. 6B is a perspective view. The light irradiation module 60 according to the present embodiment differs from the light irradiation module 50 according to the fifth embodiment in that the former includes a plurality of cylindrical lenses 65 on the light irradiation module 50 according to the fifth embodiment.

As illustrated in FIG. 6B, the cylindrical lenses 65 in the present embodiment are plano-convex cylindrical lenses having power in the X-axis direction and no power in the Y-axis direction, and are disposed so as to cover the 11 LED element groups 13G of the light irradiation module 50.

Such a configuration narrows (adjusts) the angle of spread of ultraviolet light emitted from each LED element group 13G in the X-axis direction. This makes it possible to irradiate an irradiation target with ultraviolet light at more uniform irradiation intensity in the X-axis direction.

It should be noted that the embodiments disclosed herein should be considered to be exemplary and nonrestrictive in all respects. The scope of the present invention is specified not by the above description but by the scope of claims, and is intended to include all modifications within the meaning and scope equivalent to the scope of claims.

1. A light irradiation module comprising:
a substrate defined by a first direction and a second direction perpendicular to the first direction;
n wiring patterns formed on the substrate along the first direction, where n is an integer of 2 or more; and
a plurality of light emitting diode (LED) elements that are disposed on the wiring patterns and emit light in a third direction perpendicular to the first direction and the second direction, wherein
each of the wiring patterns includes:
first, second, and third strip-shaped portions extending in the second direction and spaced from one another in the first direction;
a first connecting portion electrically connecting the first strip-shaped portion and the second strip-shaped portion; and
a second connecting portion electrically connecting the second strip-shaped portion and the third strip-shaped portion,
the first strip-shaped portion of an (i+1)-th wiring pattern among the wiring patterns is disposed between the second strip-shaped portion and the third strip-shaped portion of an i-th wiring pattern among the wiring patterns, where i is an integer of 1 to n−1,
the plurality of LED elements are disposed along the second direction on the second strip-shaped portion and the third strip-shaped portion of each of the wiring patterns,
one electrode of each of the LED elements is electrically connected to the second strip-shaped portion or the third strip-shaped portion located immediately under the LED element, and
another electrode of each of the LED elements disposed on the second strip-shaped portion and the third strip-shaped portion of the i-th wiring pattern is electrically connected to the first strip-shaped portion of the (i+1)-th wiring pattern.

2. A light irradiation module comprising:
a substrate defined by a first direction and a second direction perpendicular to the first direction;
n wiring patterns formed on the substrate along the first direction, where n is an integer of 3 or more; and
a plurality of LED elements that are disposed on the wiring patterns and emit light in a third direction perpendicular to the first direction and the second direction, wherein
each of the wiring patterns includes:
first, second, and third strip-shaped portions extending in the second direction and spaced from one another in the first direction;
a first connecting portion electrically connecting the first strip-shaped portion and the second strip-shaped portion; and
a second connecting portion electrically connecting the second strip-shaped portion and the third strip-shaped portion,
the first strip-shaped portion of an (i+1)-th wiring pattern among the wiring patterns is disposed between the second strip-shaped portion and the third strip-shaped portion of an i-th wiring pattern among the wiring patterns, where i is an integer of 1 to n−2,
the second strip-shaped portion of the (i+1)-th wiring pattern is disposed between the third strip-shaped portion of the i-th wiring pattern and the first strip-shaped portion of an (i+2)-th wiring pattern among the wiring patterns,
the third strip-shaped portion of the (i+1)-th wiring pattern is disposed between the first strip-shaped portion and the second strip-shaped portion of the (i+2)-th wiring pattern,
the plurality of LED elements are disposed along the second direction on the third strip-shaped portion of each of the wiring patterns,
one electrode of each of the LED elements is electrically connected to the third strip-shaped portion located immediately under the LED element, and
another electrode of each of the LED elements disposed on the third strip-shaped portion of the i-th wiring pattern is electrically connected to the first strip-shaped portion or the second strip-shaped portion of the (i+1)-th wiring pattern.

3. The light irradiation module according to claim 1, wherein assuming the plurality of LED elements disposed on each of the wiring patterns as a single LED element group, each of the LED element groups are disposed at a predetermined interval in the first direction.

4. The light irradiation module according to claim 3, wherein an arrangement pitch of the LED elements in each of the LED element groups in the first direction is wider than an arrangement pitch of the LED elements in the second direction.

5. The light irradiation module according to claim 3, further comprising cylindrical lenses disposed so as to cover the LED element groups.

6. The light irradiation module according to claim 3, wherein when a plurality of the light irradiation modules are coupled in the first direction, an interval in the first direction between the closest LED element groups between adjacent ones of the light irradiation modules is substantially equal to the predetermined interval.

7. The light irradiation module according to claim 1, wherein the plurality of LED elements are arranged in a single array along the second direction.

8. The light irradiation module according to claim 1, wherein the plurality of LED elements are arranged in a plurality of arrays along the second direction.

9. The light irradiation module according to claim 1, wherein the first connecting portion is a strip-shaped pattern extending in the first direction between the first strip-shaped portion and the second strip-shaped portion.

10. The light irradiation module according to claim 1, wherein the second connecting portion is a strip-shaped pattern extending in the first direction between the second strip-shaped portion and the third strip-shaped portion.

11. The light irradiation module according to claim 1, wherein the light irradiation module moves in the second direction relative to an irradiation target to be irradiated with the light.

12. A light irradiation module comprising:
a substrate defined by a first direction and a second direction perpendicular to the first direction;
n wiring patterns formed on the substrate along the first direction, where n is an integer of 2 or more; and
a plurality of LED elements that are disposed on the wiring patterns and emit light in a third direction perpendicular to the first direction and the second direction, wherein
each of the wiring patterns includes:
first, second, and third strip-shaped portions extending in the second direction and spaced from one another in the first direction;
a first connecting portion electrically connecting the first strip-shaped portion and the second strip-shaped portion; and
a second connecting portion electrically connecting the second strip-shaped portion and the third strip-shaped portion.
